(19) United States
(12) Patent Application Publication
(10) Pub. No.: US 2024/0392432 A1
(43) Pub. Date: Nov. 28, 2024

(54) METHOD FOR FORMING CARBON-CONTAINING FILM, AND METHOD FOR FORMING HARD MASK USING THE CARBON-CONTAINING FILM

(71) Applicant: Tokyo Electron Limited, Tokyo (JP)

(72) Inventors: Miyako KANEKO, Nirasaki City (JP); Tadashi MITSUNARI, Nirasaki City (JP); Yasushi FUJII, Nirasaki City (JP)

(21) Appl. No.: 18/672,092

(22) Filed: May 23, 2024

(30) Foreign Application Priority Data
May 24, 2023 (JP) 2023-085600

(51) Int. Cl. C23C 16/26; C23C 16/34; C23C 16/455

(52) U.S. Cl. CPC C23C 16/26; C23C 16/34; C23C 16/45536; C23C 16/45553

(57) ABSTRACT

A method for forming a carbon-containing film includes: preparing a substrate on which a metal-containing film is formed; performing a modification process of modifying a surface of the metal-containing film by supplying a silicon-containing gas to the substrate and by exposing the substrate to the silicon-containing gas during a first period of time; and forming the carbon-containing film having a film stress of 1 GPa or more on the modified surface of the substrate by exposing the substrate subjected to the modification process to plasma of a processing gas including a carbon-containing gas.

### CROSS-REFERENCE TO RELATED APPLICATION

This application is based upon and claims the benefit of priority from Japanese Patent Application No. 2023-085600, filed on May 24, 2023, the entire contents of which are incorporated herein by reference.

### TECHNICAL FIELD

The present disclosure relates to a method for forming a carbon-containing film, and a method for forming a hard mask using the carbon-containing film.

### BACKGROUND

Patent Document 1 discloses that an a-CF film has very poor adhesion with an insulating film or a metal film, and therefore, an adhesion layer needs to be indispensably formed between the a-CF film and the insulating layer or the metal layer. As the adhesion layer, a stacked structure of a silicon-rich oxide film and a diamond-like carbon (DLC) film has been proposed. The silicon-rich oxide film has adhesion with an underlying oxide film and the metal film and also has adhesion with the DLC film. The DLC film has adhesion with the a-CF film.

### PRIOR ART DOCUMENTS

### Patent Documents

Patent Document 1: Japanese Patent Laid-Open Publication No. 2000-058641

### SUMMARY

According to an embodiment of the present disclosure, a method for forming a carbon-containing film includes: preparing a substrate on which a metal-containing film is formed; performing a modification process of modifying a surface of the metal-containing film by supplying a silicon-containing gas to the substrate and by exposing the substrate to the silicon-containing gas during a first period of time; and forming the carbon-containing film having a film stress of 1 GPa or more on the modified surface of the substrate by exposing the substrate subjected to the modification process to plasma of a processing gas including a carbon-containing gas.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram showing an example of a processing system according to an embodiment.

FIG. 2 is a flowchart showing an example of a substrate processing method according to an embodiment.

FIG. 3 is an example of a schematic cross-sectional view of a substrate processed by the substrate processing method according to the embodiment.

FIG. 4 is a schematic cross-sectional view showing an example of a processing apparatus.

FIG. 5 is an example of a schematic cross-sectional view showing a state of a surface of a substrate subjected to a modification process.

FIG. 6 is a schematic diagram showing adhesion between a metal-containing film and a carbon-containing film in the substrate processing method of the embodiment.

FIG. 7 is a schematic diagram showing adhesion between a metal-containing film and a carbon-containing film in a substrate processing method of a reference example.

FIG. 8 is a diagram showing a state of a carbon-containing film formed on a surface of a substrate.

FIG. 9 is a graph showing an example of results of mass spectrometry.

### DETAILED DESCRIPTION

Aspects for carrying out the present disclosure will now be described with reference to the accompanying drawings. In each of the drawings, the same components will be denoted by the same reference symbols, and redundant descriptions thereof may be omitted. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### <Processing System>

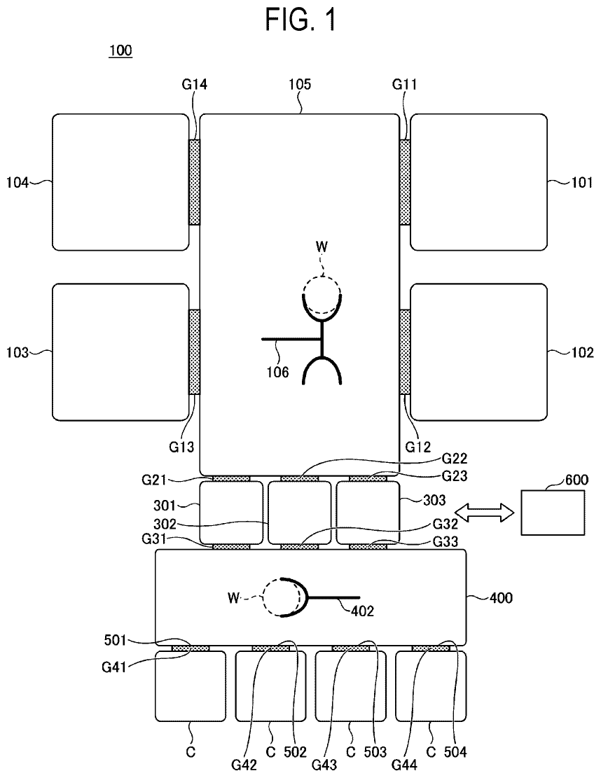

A processing system 100 used for a substrate processing method according to an embodiment will be described with reference to FIG. 1. FIG. 1 is a diagram showing an example of the processing system 100 according to the embodiment.

The processing system 100 includes processing devices 101 to 104, a vacuum transfer chamber 105, load lock chambers 301 to 303, an atmospheric-side transfer chamber 400, load ports 501 to 504, and a control device 600.

The processing devices 101 to 104 are connected to the vacuum transfer chamber 105 via gate valves G11 to G14, respectively. Interiors of the processing devices 101 to 104 are depressurized to a predetermined vacuum atmosphere. A substrate W is subjected to a desired processing in the interior of each of the processing devices 101 to 104.

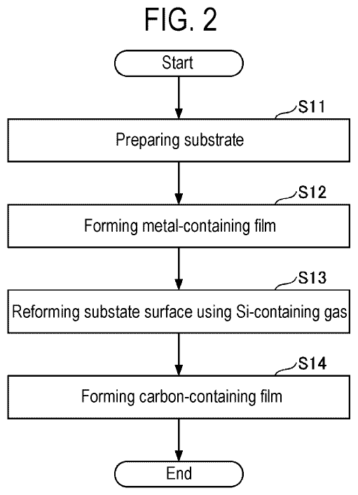

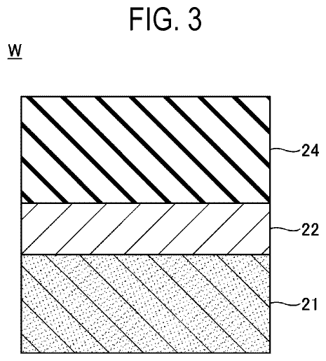

The processing device 101 is a processing device (film forming device) that forms a metal-containing film 22 (see FIG. 3 which will be described later) on a base 21 of the substrate W (see FIG. 3 which will be described later) by executing step S12 in FIG. 2 described later. The metal-containing film 22 is, for example, a TiN film.

Specifically, the processing device 101 alternately supplies a Ti-containing gas (for example, a TiCl4 gas) and a reaction gas (a nitriding gas, for example, an ammonia gas or a N2 gas) into a processing container of the processing device 101 to form the TiN film (the metal-containing film 22) on the substrate W by an atomic layer deposition (ALD) method. While the processing device 101 has been described as the film forming device that forms the metal-containing film 22 on the substrate W by the ALD method, the present disclosure is not limited thereto. For example, the processing device 101 may be a film forming device that forms the metal-containing film 22 on the substrate W by a chemical vapor deposition (CVD) method or may be a film forming device that forms the metal-containing film 22 on the substrate W by a physical vapor deposition (PVD) method.

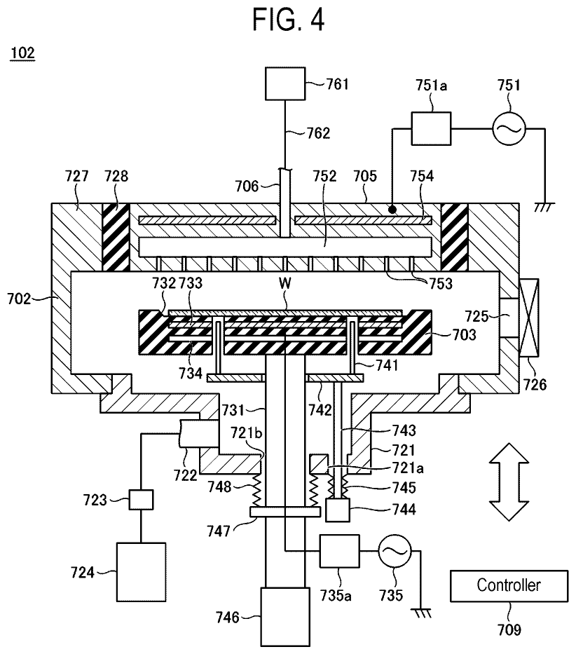

The processing device 102 is a processing device that modifies a surface of the metal-containing film 22 formed on the substrate W using a Si-containing gas to adsorb at least one of Si or SiHx, which corresponds to a monolayer, onto the surface of the substrate W by executing step S13 in FIG. 2 described later. An example of the processing device 102 will be described later with reference to FIG. 4.

The processing device 103 is a processing device (film forming device) that forms a carbon-containing film 24 (see FIG. 3 which will be described later) on the metal-containing film 22 of the substrate W by executing step S14 in FIG. 2 described later. The carbon-containing film 24 is, for example, a diamond-like carbon (DLC) film. An example of the processing device 103 will be described later with reference to FIG. 4.

The processing device 104 may be a processing device that executes the same process as that executed by any one of the processing devices 101 to 103 or a processing device (for example, an annealing device or an etching device) that executes a process different from that executed by any one of the processing devices 101 to 103. A process of forming the metal-containing film 22 on the substrate W and a process of modifying the surface of the metal-containing film 22 formed on the substrate W using the Si-containing gas may be performed by the same processing device.

An interior of the vacuum transfer chamber 105 is depressurized to a predetermined vacuum atmosphere. The vacuum transfer chamber 105 is an example of a transfer device that transfers the substrate W. The vacuum transfer chamber 105 is provided with a transfer mechanism 106 capable of transferring the substrate W in a depressurized state. The transfer mechanism 106 transfers the substrate W among the processing devices 101 to 104 and the load lock chambers 301 to 303.

The load lock chambers 301 to 303 are connected to the vacuum transfer chamber 105 via gate valves G21 to G23, respectively, and to the atmospheric-side transfer chamber 400 via gate valves G31 to G33, respectively. Interiors of the load lock chambers 301 to 303 are configured to be switched between an atmospheric environment and a vacuum atmosphere.

An interior of the atmospheric-side transfer chamber 400 is kept in an atmospheric environment. For example, a down-flow of clean air is formed in the interior of the atmospheric-side transfer chamber 400. An aligner (not shown) that aligns the substrate W is provided in the interior of the atmospheric-side transfer chamber 400. The atmospheric-side transfer chamber 400 is provided with a transfer mechanism 402. The transfer mechanism 402 transfers the substrate W among the load lock chambers 301 to 303, carriers C of the load ports 501 to 504 (to be described later), and the aligner.

The load ports 501 to 504 are provided in a wall surface of the atmospheric-side transfer chamber 400. The carrier C in which the substrates W are accommodated or an empty carrier C is attached to the load ports 501 to 504 via respective gate valves G41 to G44. As the carrier C, for example, a front opening unified pod (FOUP) may be used.

The control device 600 controls each part of the processing system 100. For example, the control device 600 executes operations of the processing devices 101 to 104, operations of the transfer mechanisms 106 and 402, opening and closing of the gate valves G11 to G14, G21 to G23, G31 to G33, and G41 to G44, and switching of internal atmospheres of the load lock chambers 301 to 303.

### <Substrate Processing Method>

Next, an example of a substrate processing method using the processing system 100 shown in FIG. 1 will be described with reference to FIGS. 2 and 3. FIG. 2 is a flowchart showing an example of the substrate processing method according to an embodiment. FIG. 3 is an example of a schematic cross-sectional view of the substrate W processed by the substrate processing method according to the embodiment.

As shown in FIG. 3, the metal-containing film 22 and the carbon-containing film 24 are formed on the substrate W including the base 21. The base 21 may be formed of, for example, a silicon substrate, or may be formed by, for example, a silicon oxide film or a silicon nitride film. Further, the base 21 may be formed to have a structure of a semiconductor device such as a magnetic tunnel junction (MTJ) element or a magneto-resistive random access memory (MRAM).

The metal-containing film 22 is, for example, a TiN film. The carbon-containing film 24 is, for example, a DLC film. The metal-containing film 22 and the carbon-containing film 24 may be used as a hard mask for the base 21 (for example, an MTJ element). In this case, a thickness of the TiN film (metal-containing film 22) may be 20 nm to 100 nm. Further, a thickness of the DLC film (carbon-containing film 24) may be 20 nm to 100 nm. The metal-containing film 22 may be other metal-containing films. For example, the metal-containing film may be a film containing tungsten (W), cobalt (Co), copper (Cu), ruthenium (Ru), magnesium (Mg), iron (Fe), or titanium (Ti), an oxide thereof, a nitride thereof, or an oxynitride thereof.

Here, the DLC film (the carbon-containing film 24) has high compressive stress. Therefore, when the DLC film (the carbon-containing film 24) is formed on the TiN film (the metal-containing film 22), the DLC film (the carbon-containing film 24) may peel off from the TiN film (the metal-containing film 22) due to the high compressive stress. In this regard, in the substrate processing method according to the embodiment shown in FIG. 2, a stacked film of the TiN film (metal-containing film 22) and the DLC film (carbon-containing film 24) may be formed by suppressing the peeling of the DLC film (the carbon-containing film 24).

In step S11, the substrate W is prepared. Here, the substrate W to be prepared has the base 21 (see FIG. 3). In this case, the carrier C in which the substrate W including the base 21 is accommodated is attached to any one of the load ports 501 to 504. Then, the control device 600 controls the transfer mechanism 402 to transfer the substrate W from the carrier C to any one of the load lock chambers 301 to 303. Further, the control device 600 controls the transfer mechanism 106 to transfer the substrate W from any one of the load lock chambers 301 to 303 to the processing device 101.

In step S12, a metal-containing film forming process of forming the metal-containing film 22 on the substrate W is performed. The control device 600 controls the processing device 101 to form the metal-containing film 22 (the TiN film) on the base 21 of the substrate W. Specifically, the metal-containing film 22 is formed on the substrate W by an ALD method. A method of forming the metal-containing film 22 is not limited to the ALD method as described above. For example, the metal-containing film 22 may be formed on the substrate W by a CVD method or a PVD method.

In step S13, a modification process of modifying a surface of the substrate W is performed with a Si-containing gas. First, the control device 600 controls the transfer mechanism 106 to transfer the substrate W from the processing device 101 to the processing device 102. Then, the control device 600 controls the processing device 102 to modify the surface of the substrate W by supplying the Si-containing gas.

Here, an example of the processing device 102 that modifies the surface of the substrate W will be described with reference to FIG. 4. FIG. 4 is a schematic cross-sectional view showing an example of the processing device 102. The processing device 102 is a device for modifying a surface of the metal-containing film 22 (the TiN film) formed on the substrate W (a surface bonded to the carbon-containing film 24) by supplying the Si-containing gas into a processing container 702 in a state in which the substrate W in the processing container 702 kept in a depressurized state is heated to a predetermined temperature (for example, 400 degrees C. or higher).

The processing device 102 includes a substantially cylindrical airtight processing container 702. An exhaust chamber 721 is provided in a central portion of a bottom wall of the processing container 702. The exhaust chamber 721 has, for example, a substantially cylindrical shape that projects downward. An exhaust flow path 722 is connected to the exhaust chamber 721 on, for example, a side surface of the exhaust chamber 721. An exhauster 724 is connected to the exhaust flow path 722 via a pressure adjuster 723. The pressure adjuster 723 includes, for example, a pressure adjustment valve such as a butterfly valve. The exhaust flow path 722 is configured to depressurize an interior of the processing container 702 by the exhauster 724. A transfer port 725 is provided in a side surface of the processing container 702. The transfer port 725 is open and closed by a gate valve 726. Loading and unloading of the substrate W between the interior of the processing container 702 and a transfer chamber (not shown) is performed via the transfer port 725.

A stage 703 configured to hold the substrate W substantially horizontally is provided inside the processing container 702. The stage 703 has a substantially circular shape when viewed in a plan view and is supported by a support member 731. A substantially circular concave portion 732 in which the substrate W having a diameter of 300 mm is placed is formed in a front surface of the stage 703. The concave portion 732 has an inner diameter slightly larger (by, for example, about 1 mm to 4 mm) than that of the substrate W. A depth of the concave portion 732 may be approximately identical to, for example, a thickness of the substrate W. The stage 703 is made of a ceramic material such as aluminum nitride (AlN). In addition, the stage 703 may be formed of a metallic material such as nickel (Ni). Instead of the concave portion 732, a guide ring for guiding the substrate W may be provided at a peripheral portion of the front surface of the stage 703.

A lower electrode 733 is embedded in the stage 703. A temperature adjustment mechanism 734 is embedded below the lower electrode 733. The temperature adjustment mechanism 734 adjusts a temperature of the substrate W placed on the stage 703 to a set temperature based on a control signal from a controller 709.

A radio-frequency (RF) power supply 735 is connected to the lower electrode 733 via a matcher 735a. The RF power supply 735 applies low-frequency (LF) power having a frequency lower than that of an RF power supply 751 (to be described later) to the lower electrode 733. The LF power generated by the RF power supply 735 is used as bias LF power for drawing ions into the substrate W. The frequency of the RF power supply 735 may be in a range of 450 kHz to 27 MHz, for example, 13.56 MHz.

The stage 703 is provided with a plurality of (for example, three) lifting pins 741 for holding, and raising and lowering the substrate W placed on the stage 703. A material of the lifting pins 741 may be, for example, ceramics such as alumina (Al₂O₃), quartz, or the like. A lower end of the lifting pin 741 is attached to a support plate 742. The support plate 742 is connected to a lifting mechanism 744 provided outside the processing container 702 via a lifting shaft 743.

The lifting mechanism 744 is installed, for example, below the exhaust chamber 721. A bellows 745 is provided between an opening 721a for the lifting shaft 743 formed on a lower surface of the exhaust chamber 721 and the lifting mechanism 744. The support plate 742 may have a shape that is raised and lowered without interfering with the support member 731 of the stage 703. The lifting pins 741 are configured to be moved upward and downward with respect to the front surface of the stage 703 by the lifting mechanism 744. In other words, the lifting pins 741 are configured to protrude from the upper surface of the stage 703.

Further, a lower end of the support member 731 passes through an opening 721b of the exhaust chamber 721 and is supported by a lifting mechanism 746 via a lifting plate 747 disposed below the processing container 702. A bellows 748 is provided between a bottom of the exhaust chamber 721 and the lifting plate 747. The interior of the processing container 702 is hermetically sealed even when the elevating plate 747 moves upward and downward.

The lifting mechanism 746 may raise and lower the stage 703 by raising and lowering the lifting plate 747. Thus, a gap between the stage 703 and a lower surface of an upper electrode plate 705 may be adjusted.

The upper electrode plate 705 is provided on a ceiling wall 727 of the processing container 702 via an insulating member 728. The upper electrode plate 705 constitutes an upper electrode and is disposed in parallel to face the lower electrode 733. The RF power supply 751 is connected to the upper electrode plate 705 via a matcher 751a. The RF power supply 751 supplies high-frequency (HF) power having a frequency higher than that of the RF power supply 735 to the upper electrode plate 705. The HF power generated by the RF power supply 751 is used as HF power for plasma generation necessary to form a film on the substrate W. The frequency of the RF power supply 751 is, for example, 450 kHz to 2.45 GHz. RF power is applied to the upper electrode plate 705 from the RF power supply 751. Thus, an RF electric field is generated between the stage 703 and the upper electrode plate 705. The upper electrode plate 705 includes a hollow gas diffusion chamber 752. A plurality of holes 753 through which a processing gas is dispersedly supplied into the processing container 702 may be evenly formed in a lower surface of the gas diffusion chamber 752. A heating mechanism 754 is embedded in the upper electrode plate 705, for example, above the gas diffusion chamber 752. The heating mechanism 754 is heated to a set temperature with power from a power supply (not shown) based on a control signal from the controller 709.

The gas diffusion chamber 752A is provided with a gas supply path 706. The gas supply path 706 is in communication with the gas diffusion chamber 752. A gas source 761 is connected to an upstream side of the gas supply path 706 via a gas line 762. The gas source 761 includes, for example, sources of various processing gases, mass flow controllers, and valves (all not shown). Here, in the modification process of modifying the surface of the substrate W, a processing gas containing silicon (Si) and hydrogen (H) may be used. Further, gas containing a Si—H bond may be used as the processing gas. Specifically, the processing gas includes at least any one selected from the group consisting of silane (SiH4), disilane (Si2H6), trisilane (Si3H8), higher-order silane, dichlorosilane (SiH2Cl2, hereinafter also referred to as DCS), trichlorosilane SiHCl3, and an organic Si precursor such as tris(dimethylamide) silane (((CH3)2N)3SiH, hereinafter also referred to as TDMAS). The processing gases may include an inert gas or a diluent gas (for example, H2, Ar, He, O2, or N2). Various gases are introduced into the gas diffusion chamber 752 from the gas source 761 via the gas line 762.

The processing device 102 includes the controller 709. The controller 709 is, for example, a computer, and includes a central processing unit (CPU), a random access memory (RAM), a read only memory (ROM), and an auxiliary memory device. The CPU operates based on a program stored in the ROM or the auxiliary memory device, and controls the operation of the processing device 102. The controller 709 may be provided inside the processing device 102 or outside the processing device 102. When the controller 709 is provided outside the processing device 102, the controller 709 may control the processing device 102 using a communication means based on a wired or wireless manner.

The controller 709 controls the temperature adjustment mechanism 734 to set the temperature of the substrate W to a predetermined temperature. The temperature adjustment mechanism 734 controls the pressure adjuster 723 and the exhauster 724 to set the interior of the processing container 702 to a predetermined pressure. The controller 709 controls the gas source 761 to supply the Si-containing gas into the processing container 702 during a predetermined period of time (the first period of time).

With such a configuration, the processing device 102 modifies the surface of the metal-containing film 22 (the TiN film) formed on the substrate W (the surface bonded to the carbon-containing film 24) by supplying the Si-containing gas into the processing container 702 in a state in which the substrate W is heated to a predetermined temperature (for example, 400 degrees C. or higher).

Here, an example of processing conditions used when modifying the surface of the metal-containing film 22 (the TiN film) is as follows.
First period of time: 2 sec to 30 sec
Temperature of Substrate: 400 degrees C. to 700 degrees C.
Processing pressure: 1,000 mT to 5,000 mT

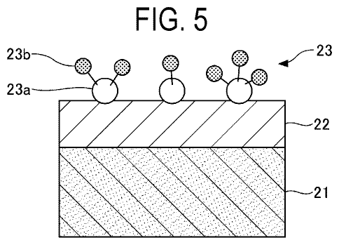

FIG. 5 is an example of a schematic cross-sectional view showing a state of the surface of the substrate W subjected to the modification process.

Here, the TiN film (the metal-containing film 22) is a hydrophilic film. By supplying the Si-containing gas onto the surface of the substrate W, a hydrophobic group 23 having Si atoms 23a and H atoms 23b is physically adsorbed onto and/or chemically bonded to the surface of the TiN film (the metal-containing film 22). That is, Ti in the TiN film and SiHx (where x is an arbitrary number) are chemically bonded to each other to form Ti—SiHx. In other words, a terminal group of the metal-containing film 22 is (—SiHx). Further, Si and/or SiHx (where x is an arbitrary number) is physically adsorbed onto the surface of the TiN film. As a result, the surface of the TiN film (the metal-containing film 22), which is a hydrophilic film, is modified into a hydrophobic surface. That is, in step S13, the surface of the substrate W is modified into the hydrophobic surface by supplying the Si-containing gas to the substrate W.

Further, the processing device 102 may modify the surface of the substrate W into the hydrophobic surface by generating plasma of the Si-containing gas. Specifically, the controller 709 forms the hydrophobic group 23 on the surface of the metal-containing film 22 using plasma of the Si-containing gas. The controller 709 controls the temperature adjustment mechanism 734 to set the temperature of the substrate W to a predetermined temperature (for example, 300 degrees C. or lower). In addition, the temperature adjustment mechanism 734 controls the pressure adjuster 723 and the exhauster 724 to set the interior of the processing container 702 to a predetermined pressure. Further, the controller 709 controls the gas source 761 to supply the Si-containing gas into the processing container 702 during the predetermined period of time (the first period of time). The controller 709 controls the RF power supply 751 to apply the HF power to the upper electrode plate 705. The controller 709 controls the RF power supply 735 to apply the LF power to the lower electrode 733. As a result, plasma of the Si-containing gas is generated, and the hydrophobic group 23 are formed on the surface of the metal-containing film 22 of the substrate W by that plasma. Further, the modification process may be performed at a low temperature with the plasma.

Here, an example of processing conditions used when modifying the surface of the metal-containing film 22 (the TiN film) is as follows.
First period of time: 2 sec to 20 sec
Temperature of substrate: 300 degrees C. to 500 degrees C.
Processing pressure: 100 mT to 5,000 mT
Plasma power: 10 W to 2,000 W

While the example in which the HF power is applied to the upper electrode plate 705 and the LP power is applied to the lower electrode 733 has been described above, the present disclosure is not limited thereto. For example, two frequencies of HF power and LF power may be applied to the upper electrode plate 705, and two frequencies of HF power and LF power may be applied to the lower electrode 733.

In step S14, the substrate W is exposed to plasma of the processing gas including the carbon-containing gas to form the carbon-containing film 24 having a film stress of 1 GPa or more on the hydrophobic surface of the substrate W (in a carbon-containing film forming process). The film stress may be in a compressive direction or in a tensile direction. That is, the carbon-containing film 24 having a film stress, an absolute value of which is 1 GPa or more, is formed. First, the control device 600 controls the transfer mechanism 106 to transfer the substrate W from the processing device 102 to the processing device 103. The control device 600 controls the processing device 103 to form the carbon-containing film 24 on the substrate W, the surface of which has been modified by plasma of the carbon-containing gas.

Here, the processing device 103 that forms the carbon-containing film 24 may be similar in configuration to, for example, the processing device 102 shown in FIG. 4. However, in the processing device 103, the type of a processing gas supplied from the gas source 761 is different.

The processing gas used in the carbon-containing film forming process includes a carbon-containing gas. The carbon-containing gas include at least one selected from the group consisting of gas CxHy containing carbon (C) and hydrogen (H), gas CxFy containing carbon (C) and fluorine (F), gas (for example, CO₂) containing carbon (C) and oxygen (O), or gas (for example, an organometallic precursor such as TDMAT) containing carbon (C) and a metal (where x and y are arbitrary numbers). The carbon-containing gas includes, for example, CH₄, C₂H₂, C₂H₄, C₃H₆, and C₆H₆. In addition, the processing gas may include an inert gas or a diluent gas (for example, H₂, Ar, He, O₂, or N₂). The processing gas may further include a hydrogen gas. Various gases are introduced into the gas diffusion chamber 752 from the gas source 761 via the gas line 762.

With such a configuration, the processing device 103 forms the carbon-containing film on the surface of the substrate W. Specifically, the controller 709 forms the carbon-containing film with the plasma of the carbon-containing gas. The controller 709 controls the temperature adjustment mechanism 734 to set the temperature of the substrate W to a predetermined temperature. The temperature adjustment mechanism 734 controls the pressure adjuster 723 and the exhauster 724 to set the interior of the processing container 702 to a predetermined pressure. The controller 709 controls the gas source 761 to supply the carbon-containing gas into the processing container 702. Further, the controller 709 controls the RF power supply 751 to apply the HF power to the upper electrode plate 705. The controller 709 controls the RF power supply 735 to apply the LF power to the lower electrode 733. As a result, the plasma of the carbon-containing gas is generated, and the carbon-containing film is formed on the substrate W by that plasma.

Here, an example of film forming conditions used when forming the carbon-containing film 24 having a film stress of 1 GPa or more is as follows.
Processing pressure: 5 mT to 200 mT
Power of plasma: 10 W to 3,000 W
Thickness of carbon-containing film: 20 nm to 100 nm

While the example in which the HF power is applied to the upper electrode plate 705 and the LF power is applied to the lower electrode 733 has been described above, the present disclosure is not limited thereto. For example, two frequencies of HF power and LF power may be applied to the upper electrode plate 705, and two frequencies of HF power and LF power may be applied to the lower electrode 733.

As described above, the hard mask including the metal-containing film 22 and the carbon-containing film 24 is formed on the substrate W. Thereafter, the control device 600 controls the transfer mechanism 106 to transfer the substrate W from the processing device 103 to any one of the load lock chambers 301 to 303. The control device 600 controls the transfer mechanism 402 to transfer the substrate W from any one of the load lock chambers 301 to 303 to the carrier C.

While the processing system 100 has been described such that the carrier C in which the substrate W including the base 21 is accommodated is attached to the load ports 501 to 504 and the substrate W on which the metal-containing film 22 and the carbon-containing film 24 have been formed is accommodated again in the carrier C, the present disclosure is not limited thereto. The processing system 100 may include at least the processing device 102 and the processing device 103, and may be configured such that the carrier C in which the substrate W including the metal-containing film 22 and the base 21 is accommodated is attached to the load ports 501 to 504, and the surface of the metal-containing film 22 is modified to accommodate the substrate W on which the carbon-containing film 24 has been formed on the metal-containing film 22 in the carrier C again.

In FIG. 1, the example in which the substrate W is transferred in a vacuum atmosphere after the metal-containing film 22 is formed and before the modification process is performed has been described. However, the present disclosure is not limited thereto. After the metal-containing film 22 is formed and before the modification process is performed, the substrate W may be transferred in an atmospheric environment. Further, while the configuration in which the substrate W is transferred in a vacuum atmosphere after the modification process is performed and before the carbon-containing film 24 is formed has been described as an example, the present disclosure is not limited thereto. The substrate W may be transferred in an atmospheric environment after the modification process is performed and before the carbon-containing film 24 is formed.

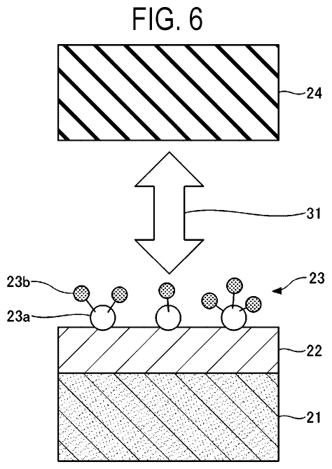

FIG. 6 is a schematic diagram showing adhesion between the metal-containing film 22 and the carbon-containing film 24 in the substrate processing method of the embodiment. In FIG. 6, an adhesion force 31 between the metal-containing film 22 and the carbon-containing film 24 is schematically shown by a size of an arrow. In the substrate processing method of the embodiment, the surface of the metal-containing film 22 is modified using the Si-containing gas (see step S13) and then the carbon-containing film 24 is formed (see step S14) by the substrate processing method shown in FIG. 2.

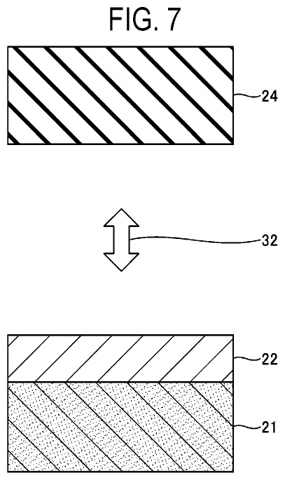

FIG. 7 is a schematic diagram showing adhesion between the metal-containing film 22 and the carbon-containing film 24 in a substrate processing method of a reference example. In FIG. 7, an adhesion force 32 between the metal-containing film 22 and the carbon-containing film 24 is schematically indicated by a size of an arrow. In the substrate processing method of the reference example, the carbon-containing film 24 is formed on the metal-containing film 22 without performing the modification process (see step S13).

In the reference example shown in FIG. 7, the TiN film (metal-containing film 22) is a hydrophilic film. In contrast, the DLC film (carbon-containing film 24) is an organic film mainly composed of a C═C bond, a C—C bond, or a C—H bond, and is a hydrophobic film. Therefore, the hydrophilic film and the hydrophobic film are bonded to each other in a bonding surface between the TiN film (the metal-containing film 22) and the DLC film (the carbon-containing film 24), so that adhesion is poor and the adhesion force 32 is small. For this reason, when a DLC film having a film stress of 1 GPa or more is formed on the TiN film, peeling of the DLC film occurs due to the film stress of the DLC film itself.

On the other hand, in the embodiment shown in FIG. 6, the hydrophobic group 23 (SiHx) having the Si atoms 23a and the H atoms 23b is physically adsorbed onto and/or chemically bonded to the surface of the TiN film (the metal-containing film 22). Therefore, the hydrophobic surface and the hydrophobic film are bonded to each other on a bonding surface between the TIN film (the metal-containing film 22) and the DLC film (the carbon-containing film 24), so adhesion is good and the adhesion force 31 is high. For this reason, even when the DLC film having a film stress of 1 GPa or more is formed on the TiN film, peeling of the DLC film may be suppressed.

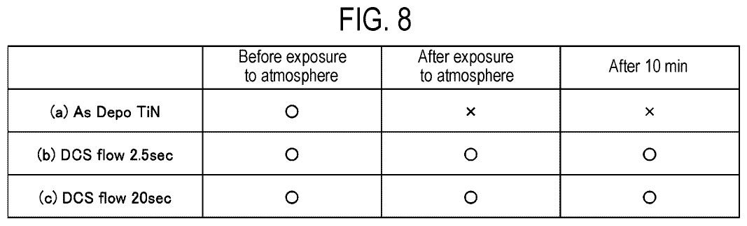

FIG. 8 is a diagram showing a state of the carbon-containing film 24 formed on the surface of the substrate W.

In FIG. 8, Case (a) represents that the TiN film is formed by the ALD method and the DLC film is formed on the TiN film without performing the modification process (“As Depo TiN”). Case (b) represents that the TiN film is formed by the ALD method, and the DLC film is formed on the TiN film after performing the modification process by supplying DCS for 2.5 seconds at a substrate temperature of 600 degrees C. (“DCS flow 2.5 sec”). Case (c) represents that the TiN film is formed by the ALD method, and the DLC film is formed on the TiN film after performing the modification process by supplying DCS for 20 seconds at a substrate temperature of 600 degrees C. (“DCS flow 20 sec”). In addition, for each of Cases (a) to (c), peeling of the DLC film was observed in a state after the formation of the DLC film and before exposure to the atmosphere, a state immediately after exposure to the atmosphere, and a state after 10 minutes from exposure to the atmosphere. In FIG. 8, symbol “O” indicates that there was no peeling of the film, and symbol “X” indicates that there was peeling of the film. The DLC film was formed with a film compressive stress of −3 GPa, a film density of 2.1 g/cm³, and a film thickness of 40 nm.

As shown in Case (a) of FIG. 8, when the DLC film is formed on the TiN film without the modification process, the film peeled off immediately after exposure to the atmosphere, and, after 10 minutes have elapsed from the exposure to the atmosphere, the entire surface of the DLC film was peeled off.

In contrast, as shown in Cases (b) and (c) of FIG. 8, when the DLC film is formed on the TiN film subjected to the modification process, no peeling of the DLC film occurred both immediately after the exposure to the atmosphere and after 10 minutes from the exposure to the atmosphere. Although not shown, in any of both Cases (b) and (c), no peeling of the DLC film occurred even after one month had elapsed from the exposure to the atmosphere.

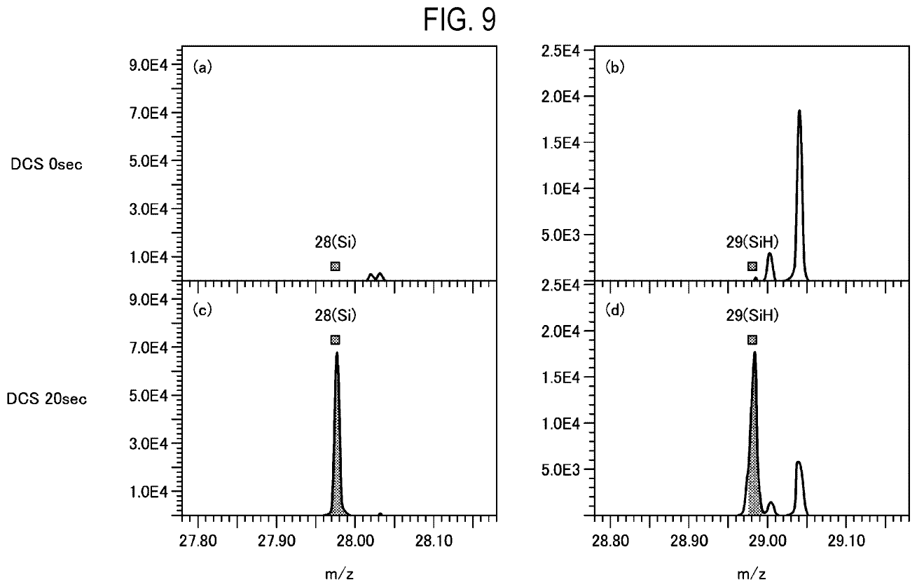

FIG. 9 is a graph showing an example of results of mass spectrometry.

Here, the TiN film was analyzed using a time-of-flight secondary ion mass spectrometry (TOF-SIMS). Cases (a) and (b) show analysis results in the substrate W after forming the TiN film by the ALD method and before supplying DCS (“DCS 0 sec”). Cases (c) and (d) show analysis results in the substrate W after forming the TiN film by the ALD method and subsequently supplying DCS for 20 seconds at a substrate temperature of 600 degrees C. to perform the modification process (“DCS 20 sec”). In addition, Cases (a) and (c) show analysis results for Si (m/z=28), and Cases (b) and (d) show analysis results for Si—H (m/z=29).

As shown in FIG. 9, it was confirmed that Si—H was physically adsorbed onto and/or chemically bonded to the surface of the TiN film by supplying DCS for 20 seconds at a substrate temperature of 600 degrees C. to perform the modification process. Although not shown, it was confirmed that Si—H was physically adsorbed onto and/or chemically bonded to the surface of the TiN film by supplying DCS for 2.5 seconds at a substrate temperature of 600 degree C. to perform the modification process, similar to the case in which DCS was supplied for 20 seconds to perform the modification process.

As described above, before forming the carbon-containing film 24 on the surface of the substrate W, the surface of the metal-containing film 22 is first modified into the hydrophobic surface by the modification process. Then, the carbon-containing film 24 is formed on the hydrophobic surface, thereby improving adhesion between the metal-containing film 22 and the carbon-containing film 24. This makes it possible to suppress the peeling of the carbon-containing film 24.

In addition, as film density of the DLC film becomes higher, stress of the DLC film tends to increase. According to the substrate processing method according to the embodiment, film peeling may be suppressed even in the DLC film with a high film density and high stress of 1 GPa or more.

According to the present disclosure in some embodiments, it is possible to provide a method for forming a carbon-containing film while suppressing film peeling.

While embodiments of the method of forming the carbon-containing film 24 on the metal-containing film 22 have been described, the present disclosure is not limited the above-described embodiments. Various changes and modifications may be made within the scope of the claims.

What is claimed is:

1. A method for forming a carbon-containing film, the method comprising:
preparing a substrate on which a metal-containing film is formed;
performing a modification process of modifying a surface of the metal-containing film by supplying a silicon-containing gas to the substrate and by exposing the substrate to the silicon-containing gas during a first period of time; and
forming the carbon-containing film having a film stress of 1 GPa or more on the modified surface of the substrate by exposing the substrate subjected to the modification process to plasma of a processing gas including a carbon-containing gas.

2. The method of claim 1, wherein the performing the modification process includes forming a hydrophobic group on the surface.

3. The method of claim 1, wherein the silicon-containing gas is a gas containing silicon (Si) and hydrogen (H).

4. The method of claim 3, wherein the silicon-containing gas has a Si—H bond.

5. The method of claim 3, wherein the silicon-containing gas includes at least one selected from a group consisting of SiH₄, Si₂H₆, Si₃H₈, higher-order silane, SiH₂Cl₂, SiHCl₃, and an organic silicon (Si) precursor.

6. The method of claim 1, wherein the first period of time is in a range of 2 seconds to 30 seconds.

7. The method of claim 1, wherein a temperature of the substrate in the performing the modification process is in a range of 400 degrees C. to 700 degrees C.

8. The method of claim 1, wherein the metal-containing film is a TiN film.

9. The method of claim 8, wherein a thickness of the TiN film is 20 nm to 100 nm.

10. The method of claim 1, wherein the carbon-containing gas includes at least one selected from a group consisting of a gas containing carbon (C) and hydrogen (H), a gas containing carbon (C) and fluorine (F), a gas containing carbon (C) and oxygen (O), and a gas containing carbon (C) and a metal.

11. The method of claim 10, wherein the processing gas includes an inert gas.

12. The method of claim 10, wherein the processing gas further includes a hydrogen gas.

13. The method of claim 10, wherein a processing pressure in the forming the carbon-containing film is 5 mT to 200 mT.

14. The method of claim 10, wherein plasma power in the forming the carbon-containing film is 10 W to 300 W.

15. The method of claim 10, wherein a thickness of the carbon-containing film is 20 nm to 100 nm.

16. A method for forming a hard mask on a substrate using a carbon-containing film, the method comprising:
preparing the substrate;
forming a metal-containing film on the substrate;
modifying a surface of the metal-containing film by supplying a silicon-containing gas to the substrate on which the metal-containing film has been formed and by exposing the substrate to the silicon-containing gas during a first period of time; and
forming the carbon-containing film having a film stress of 1 GPa or more on the modified surface of the substrate, by exposing the substrate on which the modifying the surface of the metal-containing film has been performed to plasma of a processing gas including a carbon-containing gas, and forming the hard mask including the metal-containing film and the carbon-containing film.
